(19) United States
(12) Patent Application Publication
(10) Pub. No.: US 2013/0062696 A1
(43) Pub. Date: Mar. 14, 2013

(54) SOI Semiconductor Structure with a Hybrid of Coplanar Germanium and III-V, and Preparation Method thereof

(71) Applicants: Zengfeng Di, Shanghai (CN); Jiantao Bian, Shanghai (CN); Miao Zhang, Shanghai (CN); Xi Wang, Shanghai (CN)

(72) Inventors: Zengfeng Di, Shanghai (CN); Jiantao Bian, Shanghai (CN); Miao Zhang, Shanghai (CN); Xi Wang, Shanghai (CN)

(73) Assignee: SHANGHAI INSTITUTE OF MICROSYSTEM AND INFORMATION TECHNOLOGY, CHINESE ACADEMY OF SCIENCES, Shanghai (CN)

(21) Appl. No.: 13/636,128

(22) PCT Filed: May 16, 2012
(86) PCT No.: PCT/CN2012/075548

§ 371 Date: Sep. 20, 2012

(30) Foreign Application Priority Data
May 16, 2011 (CN) 201110126382.9

(51) Int. Cl. H01L 27/12; H01L 21/20; H01L 21/84

(52) U.S. Cl. 257/351; 438/429; 438/400; 257/E21.7; 257/E27.112; 257/E21.119

(57) ABSTRACT

The present invention provides an SOI semiconductor structure with a hybrid of coplanar germanium (Ge) and III-V, and a method for preparing the same. A heterogeneous integrated semiconductor structure with a hybrid of Ge and the group III-V semiconductor material coplanar on an insulator includes at least one Ge substrate formed on the insulating layer, and the other substrate is a group III-V semiconductor material formed on the Ge semiconductor. The preparation method for forming the semiconductor structure includes: preparing a global Ge on insulator substrate structure; preparing a group III-V semiconductor material layer on the Ge on insulator substrate structure; performing photolithography and etching for the first time to make a patterned window to the above of a Ge layer to form a recess; preparing a spacer in the recess; preparing a Ge film by selective epitaxial growth; performing a chemical mechanical polishing to obtain the heterogeneous integrated semiconductor structure with a hybrid of Ge and the group III-V semiconductor material being coplanar; removing the spacer and a defective Ge layer part close to the spacer; implementing isolation between Ge and the group III-V semiconductor material; and preparing a high-performance CMOS device including a Ge PMOS and a III-V NMOS by forming an MOS structure.

### BACKGROUND OF THE INVENTION

1. Field of Invention

The present invention relates to the field of semiconductor manufacturing, specifically to a coplanar heterogeneous integrated semiconductor structure, and more particularly to a heterogeneous integrated substrate material with germanium (Ge) and a group III-V semiconductor material coplanar on insulator, and a high-performance CMOS device manufactured according to a preparation method of the semiconductor structure.

2. Description of Related Arts

With the development of semiconductor technologies and especially when the device characteristics dimension scales down to 22 nm node technology or beyond, it is required to adopt a high-mobility semiconductor material such as Ge or a group III-V semiconductor material. Ge has high electron mobility and high hole mobility, yet undesirable N-type metal oxide semiconductor (NMOS) performance due to the limitation of device process factors (such as n-type doping and n-type ohmic contact of Ge). However, the group III-V semiconductor material such as GaAs has high electron mobility and may be used to manufacture a high-performance NMOS device.

According to the International Technology Roadmap for Semiconductors (ITRS), it is required to research and manufacture a heterogeneous integrated and high-mobility semiconductor substrate material with both a group III-V material and a Ge material on insulator, so as to ensure that integrated circuit technologies continue to develop with or ahead of the Moore law. Meanwhile, the research and manufacturing of the heterogeneous integrated and high-mobility semiconductor substrate material with both the group III-V material and the Ge material on insulator also provide high-performance substrate materials to implement the integration of multifunctional chips such as the monolithic optoelectronic integrated chip or MEMS.

However, at present, there is no feasible heterogeneous integrated substrate with a hybrid of Ge and the group III-V semiconductor material coplanar on insulator, and a method for preparing the structure. The group III-V (compounds) semiconductor material refers to a compound formed by a group III element (such as, B, Al, Ga, or In) and a group V element (such as N, P, As, or Sb) in the periodic table of elements.

Therefore, it is expected to put forward a heterogeneous integrated substrate with a hybrid of Ge and the group III-V semiconductor material coplanar on insulator, and a method for preparing the structure of the substrate; further implement a high-performance CMOS device based on the method.

### SUMMARY OF THE PRESENT INVENTION

Therefore, an objective of the present invention is to provide a heterogeneous integrated substrate with a hybrid of Ge and a group III-V semiconductor material coplanar on insulator, a method for preparing the structure of the substrate, and a high-performance CMOS device manufactured according to the substrate and the structure thereof.

In a first aspect, the present invention provides a heterogeneous integrated semiconductor structure with a hybrid of Ge and a group III-V semiconductor material coplanar on insulator, especially, a heterogeneous integrated substrate material with a hybrid of Ge and a group III-V semiconductor material coplanar on an insulator, and a method for preparing the substrate material.

The heterogeneous integrated semiconductor substrate material with Ge and the group III-V semiconductor material coplanar on the insulator according to the present invention is disposed with a silicon support substrate, a silicon dioxide buried oxide layer, a Ge semiconductor layer, a group III-V semiconductor material layer, and an isolation medium material between Ge and the group III-V semiconductor material layer. The silicon dioxide buried oxide layer is located on the silicon support substrate, the Ge semiconductor layer is located on the silicon dioxide buried oxide layer, the group III-V semiconductor material layer is located on a part of the Ge semiconductor layer, the top of the group III-V semiconductor material layer is coplanar with the Ge semiconductor layer laterally adjacent to the group III-V semiconductor material layer. The isolation medium material between Ge and the group III-V semiconductor material is located on the silicon dioxide buried oxide layer. And in a transverse structure, two sides of the isolation medium material are connected to the Ge semiconductor layer and the group III-V semiconductor material respectively.

The semiconductor structure according to the present invention comprises the foregoing substrate material, and therefore, the semiconductor structure at least comprises two devices, where at least one of the devices is located on the Ge semiconductor layer and the other device is located on the group III-V semiconductor material layer.

The preparation method according to the present invention comprises: preparing a global Ge on insulator substrate structure; preparing a group III-V semiconductor material layer on the Ge on insulator substrate structure; performing photolithography and etching for the first time to make a patterned window to the above of the Ge layer to form a recess; preparing a spacer in the recess; preparing a Ge film by selective epitaxial growth; performing chemical mechanical polishing to obtain a heterogeneous integrated semiconductor structure with Ge and a group III-V semiconductor material being coplanar; removing the spacer and a defective Ge layer part close to the spacer; implementing isolation between Ge the group III-V semiconductor material; and preparing a Ge PMOS and a III-V NMOS by forming an MOS structure. Therefore, by using the preparation method of the heterogeneous integrated semiconductor structure with a hybrid of Ge and the group III-V semiconductor material coplanar on insulator according to the present invention, a high-performance CMOS device is implemented on the substrate structure with a hybrid of Ge and the group III-V semiconductor material coplanar on insulator.

Preferably, in the foregoing preparation method of the heterogeneous integrated semiconductor structure with a hybrid of Ge and the group III-V semiconductor material coplanar on insulator, the group III-V semiconductor material layer comprises materials such as GaAs, AlAs, AlGaAs, or InGaAs.

Preferably, in the foregoing preparation method of the heterogeneous integrated semiconductor structure with a hybrid of Ge and the group III-V semiconductor material coplanar on insulator, the spacer is a silicon dioxide spacer or a silicon nitride spacer.

Preferably, in the foregoing preparation method of the heterogeneous integrated semiconductor structure with a hybrid of Ge and the group III-V semiconductor material coplanar on insulator, epitaxy technology or bonding technology is used in the step of preparing the group III-V semiconductor material layer on the Ge on insulator substrate structure.

Preferably, in the foregoing preparation method of the heterogeneous integrated semiconductor structure with a hybrid of Ge and the group III-V semiconductor material coplanar on insulator, shallow-trench isolation technology is used in the step of removing the spacer and the defective Ge layer part close to the spacer. Further preferably, the photolithography is performed for the second time during the shallow-trench isolation technology.

Preferably, in the foregoing preparation method of the heterogeneous integrated semiconductor structure with a hybrid of Ge and the group III-V semiconductor material coplanar on insulator, silicon dioxide is used in the step of implementing the isolation between Ge and the group III-V semiconductor material to isolate Ge from the group III-V semiconductor material. Further preferably, the deposition of silicon dioxide is implemented by high-density plasma deposition technology.

In a second aspect, the present invention provides a high-performance CMOS device manufactured according to the preparation method of the heterogeneous integrated semiconductor structure with a hybrid of Ge and the group III-V semiconductor material coplanar on insulator that is described according to the first aspect of the present invention.

Through the preparation method of the heterogeneous integrated semiconductor structure with a hybrid of Ge and the group III-V semiconductor material coplanar on insulator that is described according to the first aspect of the present invention, it can be understood by persons skilled in the art that, the CMOS device according to the second aspect of the present invention can also achieve the beneficial technical effects capable of being achieved according to the preparation method of the heterogeneous integrated semiconductor structure with a hybrid of Ge and the group III-V semiconductor material coplanar on insulator that is described according to the first aspect of the present invention.

### BRIEF DESCRIPTION OF THE DRAWINGS

With reference to the accompanying drawings and the following detailed description, the present invention will be more easily and completely understood, and the accompanying advantages and features thereof will also be more easily understood, where:

FIG. 1 is a flowchart of a method for manufacturing a CMOS device according to an embodiment of the present invention

FIG. 2 is a schematic structural view of a semiconductor obtained after a first step S0 shown in FIG. 1.

FIG. 3 is a schematic structural view of a semiconductor obtained after a second step S1 shown in FIG. 1.

FIG. 4 is a schematic structural view of a semiconductor obtained after a third step S2 shown in FIG. 1.

FIG. 5 is a schematic structural view of a semiconductor obtained after a fourth step S3 shown in FIG. 1.

FIG. 6 is a schematic structural view of a semiconductor obtained after a fifth step S4 shown in FIG. 1.

FIG. 7 is a schematic structural view of a semiconductor obtained after a sixth step S5 shown in FIG. 1.

FIG. 8 is a schematic structural view of a semiconductor obtained after a seventh step S6 shown in FIG. 1.

FIG. 9 is a schematic structural view of a semiconductor obtained after an eighth step S7 shown in FIG. 1.

FIG. 10 is a schematic structural view of a semiconductor obtained after a ninth step S8 shown in FIG. 1.

It should be noted that the accompanying drawings are used for describing the present invention, but are not intended to limit the present invention. It should be noted that the accompanying drawings indicating structures may not be drawn according to a proportion. Moreover, in the accompanying drawings, the same or similar elements are marked by the same or similar marks.

### DETAILED DESCRIPTION OF THE PREFERRED EMBODIMENTS

To make the content of the present invention clearer and more comprehensible, the content of the present invention will be described in detail in the following with reference to the specific embodiments and the accompanying drawings.

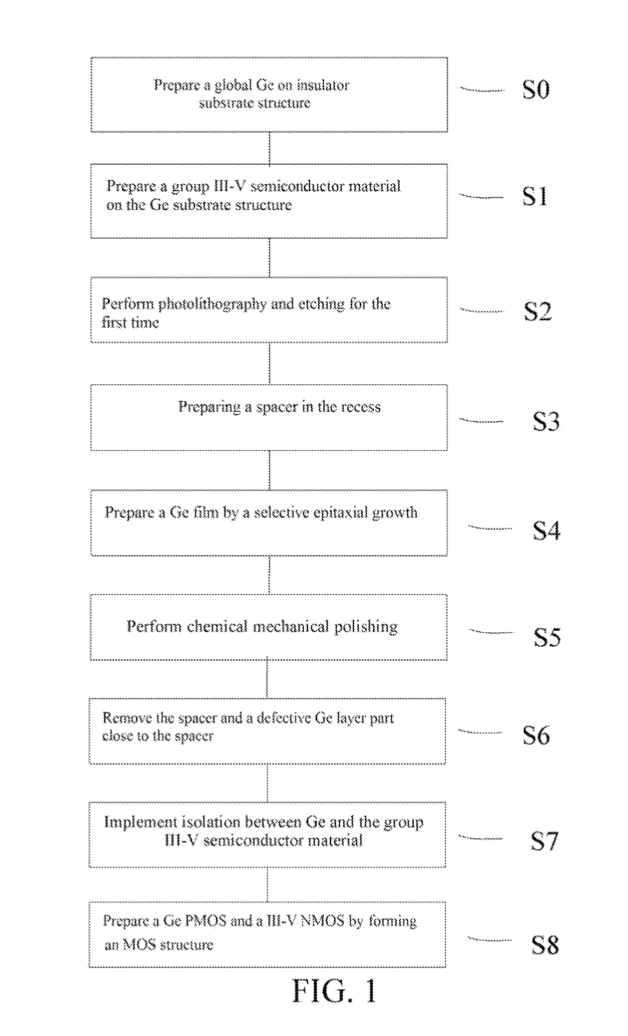

FIG. 1 is a flowchart of a preparation method of a heterogeneous integrated semiconductor structure with a hybrid of Ge and a group III-V semiconductor material coplanar on insulator.

As shown in FIG. 1, the preparation method of the heterogeneous integrated semiconductor structure with a hybrid of Ge and the group III-V semiconductor material coplanar on insulator includes the following steps.

In a first Step S0, a global Ge on insulator substrate structure is used as an initial substrate. More specifically, the global Ge on insulator substrate structure may be prepared by a method such as Smart-Cut™ technology or Ge oxidation and concentration technology. The initial substrate includes a silicon substrate sub, a buried oxide layer BOX on the silicon substrate sub, and a Ge layer G generated on the buried oxide layer BOX. FIG. 2 is a schematic view of a semiconductor structure obtained after the first step S0 shown in FIG. 1.

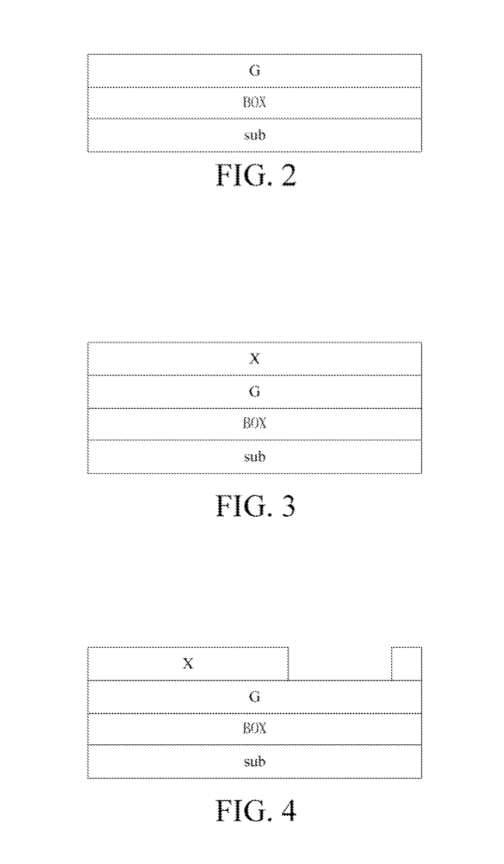

In a second Step S1, a group III-V semiconductor material layer X is prepared on the Ge on insulator substrate structure. FIG. 3 is a schematic view of a semiconductor device obtained after the second step S1 shown in FIG. 1. Preferably, epitaxy technology or bonding technology is used in the step of preparing the group III-V semiconductor material layer X on the Ge on insulator substrate structure.

It should be noted that, the group III-V semiconductor material herein refers to a compound semiconductor material formed by a group III element (such as, B, Al, Ga, or In) and s group V element (such as N, P, As, or Sb) in the periodic table of elements.

Moreover, preferably, in a specific embodiment, the group III-V semiconductor material in the group III-V semiconductor material layer X includes but is not limited to GaAs, AlAs, AlGaAs, or InGaAs. In addition, when the group III-V semiconductor material adopts GaAs, AlAs, AlGaAs, or InGaAs, a finally obtained CMOS device has the best performance.

In a third Step S2, photolithography and etching are performed for the first time to make a patterned window to the above of the Ge layer to form a recess, that is, the Ge layer G is used as a stopping layer in the etching for the first time, and the etching is not performed on the Ge layer. FIG. 4 is a schematic view of a semiconductor structure obtained after the third step S2 shown in FIG. 1.

In a fourth Step S3, a spacer S is prepared in the recess. FIG. 5 is a schematic view of a semiconductor structure obtained after a fourth step S3 shown in FIG. 1. Preferably, in a specific embodiment, the spacer is a silicon dioxide spacer or a silicon nitride spacer.

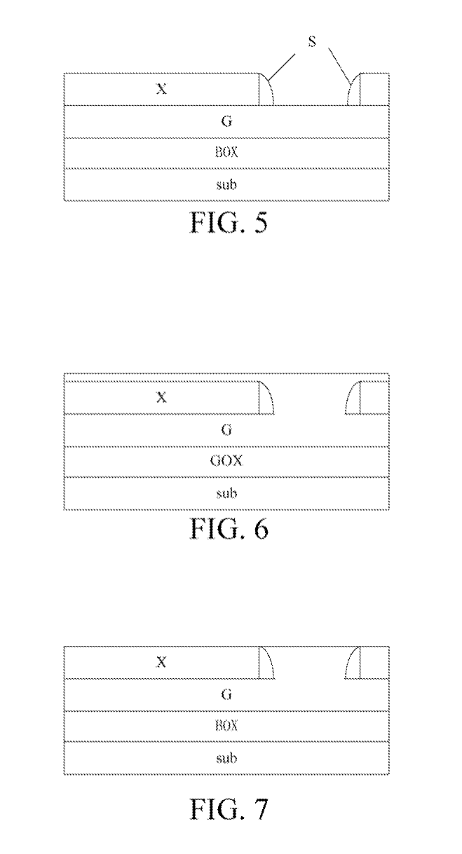

In a fifth Step S4, a Ge film G is prepared by selective epitaxial growth. FIG. 6 is a schematic view of a semiconductor structure obtained after the fifth step S4.

In the sixth Step S5, chemical mechanical polishing (CMP) is performed to obtain a heterogeneous integrated semiconductor structure with a hybrid of Ge and the group III-V semiconductor material being coplanar. FIG. 7 is a schematic view of a semiconductor structure obtained after the sixth step S5 shown in FIG. 1.

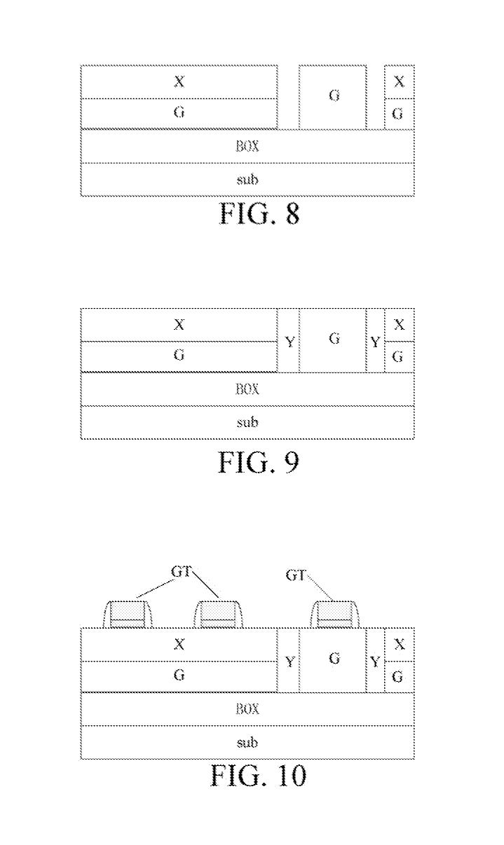

In the seventh Step S6, the spacer and a defective Ge layer part close to the spacer are removed. FIG. 8 is a schematic view of a semiconductor structure obtained after the seventh step S6 shown in FIG. 1. Preferably, in a specific embodiment, shallow-trench isolation technology is used in the step of removing the spacer and the defective Ge layer part close to the spacer. Further preferably, the photolithography is performed for the second time during the shallow-trench isolation technology.

It should be noted that, in fact, a small trench is formed on the buried oxide layer BOX in the seventh step S6, that is, an opening structure using the buried oxide layer BOX as a bottom portion.

In an eighth Step S7, isolation Y is implemented between Ge and the group III-V semiconductor material. FIG. 9 is a schematic view of a semiconductor structure obtained after the eighth step S7. Preferably, in a specific embodiment, silicon dioxide is used as an isolation material Y in the step of implementing the isolation Y between Ge and the group III-V semiconductor material to isolate Ge from the group III-V semiconductor material. Further preferably, the silicon dioxide is implemented by high-density plasma deposition technology.

In a ninth Step S8, a Ge PMOS and a III-V NMOS are prepared by forming an MOS structure GT. A method for forming the MOS structure GT may be any proper method publicly known in the field, and the present invention does not limit specific methods or steps for forming the MOS structure GT. Moreover, FIG. 10 shows three MOS structures GT, but the three MOS structures GT are merely exemplary, and are not intended to specifically limit the number of and a positional interval between the MOS structures GT in the present invention.

FIG. 10 is a schematic view of a semiconductor structure obtained after the ninth step S8 shown in FIG. 1. It can be seen from the foregoing description that, through steps S0 to S8, a high-performance CMOS device is implemented on a semiconductor substrate structure with a hybrid of Ge and the group III-V semiconductor material coplanar on insulator by the preparation method provided in the embodiment of the present invention.

In addition, the foregoing preparation method of the heterogeneous integrated semiconductor structure with a hybrid of Ge and the group III-V semiconductor material coplanar on insulator is especially applicable to the manufacturing of a CMOS device when the device characteristic dimension scales down to 22 nm or beyond. When the device characteristic dimension scales down to 22 nm or beyond, a CMOS device manufactured using the foregoing preparation method of the heterogeneous integrated semiconductor structure with a hybrid of Ge and the group III-V semiconductor material coplanar on insulator is especially superior to a CMOS device manufactured by a CMOS device manufacturing method in the prior art.

According to another embodiment of the present invention, the present invention further relates to a CMOS device manufactured through a process of the preparation method of the heterogeneous integrated semiconductor structure with a hybrid of Ge and the group III-V semiconductor material coplanar on insulator that is shown in FIG. 1, for example, a CMOS device located on the semiconductor substrate with a hybrid of Ge and the group III-V semiconductor material coplanar on insulator that is shown in FIG. 10.

It should be understood that, although the present invention is described with preferred embodiments in the above, the foregoing embodiments are not intended to limit the present invention. Any persons skilled in the art can make many possible changes and modifications to the technical solutions of the present invention or modify the technical solutions into equivalent embodiments with the same changes by using the foregoing disclosed technical content, as long as such changes and modifications do not depart from the scope of the technical solutions of the present invention. Therefore, without departing from the content of the technical solutions of the present invention, any simple modifications, equivalent changes and improvements made to the foregoing embodiments according to the technical essence of the present invention still fall within the protection scope of the technical solutions of the present invention.

1. A heterogeneous integrated semiconductor substrate material with a hybrid of germanium (Ge) and a group III-V semiconductor material coplanar on insulator, wherein the semiconductor substrate material is disposed with a silicon support substrate, a silicon dioxide buried oxide layer, a Ge semiconductor layer, a group III-V semiconductor material layer, and an isolation medium material between Ge and the group III-V semiconductor material; and
the silicon dioxide buried oxide layer is located on the silicon support substrate, the Ge semiconductor layer is located on the silicon dioxide buried oxide layer, the group III-V semiconductor material layer is located on a part of the Ge semiconductor layer, the top of the group III-V semiconductor material layer is coplanar with the Ge semiconductor layer laterally adjacent to the group III-V semiconductor material layer, the isolation medium material between Ge and the group III-V semiconductor material is located on the silicon dioxide buried oxide layer, and in a lateral structure, two sides of the isolation medium material are connected to the Ge semiconductor layer and the group III-V semiconductor material respectively.

2. A semiconductor structure, comprising the substrate material as in claim 1, wherein the semiconductor structure at least comprises two devices, at least one of the devices is located on the Ge semiconductor layer and the other device is located on the group III-V semiconductor material layer.

3. The semiconductor structure as in claim 2, wherein a device on the Ge semiconductor is an PMOS and a device on the group III-V semiconductor material layer is a NMOS.

4. The semiconductor structure as in claim 2, wherein the Ge semiconductor layer used for the PMOS device is a Ge semiconductor layer partially exposed to a surface.

5. A preparation method of the substrate material as in claim 1, wherein the specific steps of the method comprise:
(1) preparing a global Ge on insulator substrate structure;
(2) preparing a group III-V semiconductor material layer on the Ge on insulator substrate structure;
(3) performing photolithography and etching for the first time to make a patterned window to the above of the Ge layer to form a recess;
(4) preparing a spacer in the recess;
(5) preparing a Ge film by a selective epitaxial growth;
(6) performing chemical mechanical polishing to obtain a heterogeneous integrated semiconductor structure with a hybrid of Ge and a group III-V semiconductor material being coplanar;
(7) removing a spacer and a defective Ge layer part close to the spacer;
(8) implementing isolation between Ge and the group III-V semiconductor material; and
(9) preparing a Ge PMOS and a III-V NMOS by forming an MOS structure.

6. The substrate material as in claim 1, wherein the group III-V semiconductor material comprises GaAs, AlAs, AlGaAs, or InGaAs.

7. The substrate material as in claim 1, wherein the group III-V semiconductor material is formed on the Ge semiconductor.

8. The substrate material as in claim 1, wherein the spacer is a silicon dioxide spacer or a silicon nitride spacer.

9. The substrate material as in claim 1, wherein epitaxy technology or bonding technology is used in the step of preparing the group III-V semiconductor material layer on the Ge on insulator substrate structure.

10. The substrate material as in claim 1, wherein shallow trench isolation technology is used in the step of removing the spacer and the defective Ge layer part close to the spacer.

11. The substrate material as in claim 1, wherein silicon dioxide is used in the step of implementing isolation between Ge and the group III-V semiconductor material to isolate Ge from the group III-V semiconductor material.

12. The semiconductor structure as in claim 3, wherein the Ge semiconductor layer used for the PMOS device is a Ge semiconductor layer partially exposed to a surface.

13. A preparation method of the structure as in claim 2, wherein the specific steps of the method comprise:
(1) preparing a global Ge on insulator substrate structure;
(2) preparing a group III-V semiconductor material layer on the Ge on insulator substrate a structure;
(3) performing photolithography and etching for the first time to make a patterned window to the above of the Ge layer to form a recess;
(4) preparing a spacer in the recess;
(5) preparing a Ge film by a selective epitaxial growth;
(6) performing chemical mechanical polishing to obtain a heterogeneous integrated semiconductor structure with a hybrid of Ge and a group III-V semiconductor material being coplanar;
(7) removing a spacer and a defective Ge layer part close to the spacer;
(8) implementing isolation between Ge and the group III-V semiconductor material; and
(9) preparing a Ge PMOS and a III-V NMOS by forming an MOS structure.

14. The method as in claim 5, wherein the group III-V semiconductor material comprises GaAs, AlAs, AlGaAs, or InGaAs.

15. The method as in claim 5, wherein the group III-V semiconductor material is formed on the Ge semiconductor.

16. The method as in claim 5, wherein the spacer is a silicon dioxide spacer or a silicon nitride spacer.

17. The method as in claim 5, wherein epitaxy technology or bonding technology is used in the step of preparing the group III-V semiconductor material layer on the Ge on insulator substrate structure.

18. The method as in claim 5, wherein shallow trench isolation technology is used in the step of removing the spacer and the defective Ge layer part close to the spacer.

19. The method as in claim 5, wherein silicon dioxide is used in the step of implementing isolation between Ge and the group III-V semiconductor material to isolate Ge from the group III-V semiconductor material.
